(19) United States
(12) Patent Application Publication
(10) Pub. No.: US 2009/0196091 A1
(43) Pub. Date: Aug. 6, 2009

(54) Self-aligned phase change memory

(76) Inventors: Derchang Kau, Cupertino, CA (US); Gianpaolo Spadini, Campbell, CA (US); Wim Deweerd, San Jose, CA (US)

Correspondence Address: TROP, PRUNER & HU, P.C., 1616 S. VOSS RD., SUITE 750, HOUSTON, TX, 77057-2631, US

(21) Appl. No.: 12/012,107

(22) Filed: Jan. 31, 2008

(51) Int. Cl. G11C 11/00; H01L 21/06

(52) U.S. Cl. 365/163; 438/102; 365/148

(57) ABSTRACT

A self-aligned phase change memory may be formed by blanket depositing a number of layers and then using patterning techniques to define the individual cells. In one embodiment, a layer of phase change material may be blanket deposited over a lower electrode material. The structure may then be patterned and etched to form a plurality of spaced, parallel elongate first strips. Those strips may then be covered with a filler material, planarized, and then patterned again in a transverse direction to form a plurality of transverse, spaced, parallel second strips. The resulting structure then has singulated phase change material with connections in at least one of the row or column direction. The singulated the phase change material is self-aligned to underlying and overlying electrodes.

### BACKGROUND

This invention relates generally to phase change memories.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, perspective view of one embodiment of the present invention;

FIG. 2 is an enlarged, perspective view corresponding to FIG. 1 at a subsequent stage in accordance with one embodiment;

FIG. 3 is an enlarged, perspective view at a subsequent stage in accordance with one embodiment;

FIG. 4 is an enlarged, perspective view at a subsequent stage in accordance with one embodiment;

FIG. 5 is an enlarged, perspective view at a subsequent stage in accordance with one embodiment;

FIG. 6 is an enlarged, cross-sectional view taken generally along the line 6-6 in FIG. 5;

FIG. 7A is an enlarged, cross-sectional view of another embodiment in accordance with the present invention;

FIG. 7B is an enlarged, cross-sectional view at a subsequent state to that shown in FIG. 7A in accordance with one embodiment;

FIG. 8 is an enlarged, cross-sectional view at a subsequent stage to that shown in FIG. 7B in accordance with one embodiment;

FIG. 9 is a partial, enlarged, perspective view after subsequent processing of a piece from the embodiment shown in FIG. 8;

FIG. 10 is an enlarged, perspective view of another embodiment;

FIG. 11 is an enlarged, perspective view at a subsequent stage to that shown in FIG. 10 in accordance with one embodiment;

FIG. 12 is an enlarged, perspective view at a subsequent stage in accordance with one embodiment;

FIG. 13 is an enlarged, perspective view at a subsequent stage in accordance with one embodiment;

FIG. 14 is an enlarged, perspective view at a subsequent stage in accordance with one embodiment; and

FIG. 15 is a system depiction in accordance with one embodiment.

### DETAILED DESCRIPTION

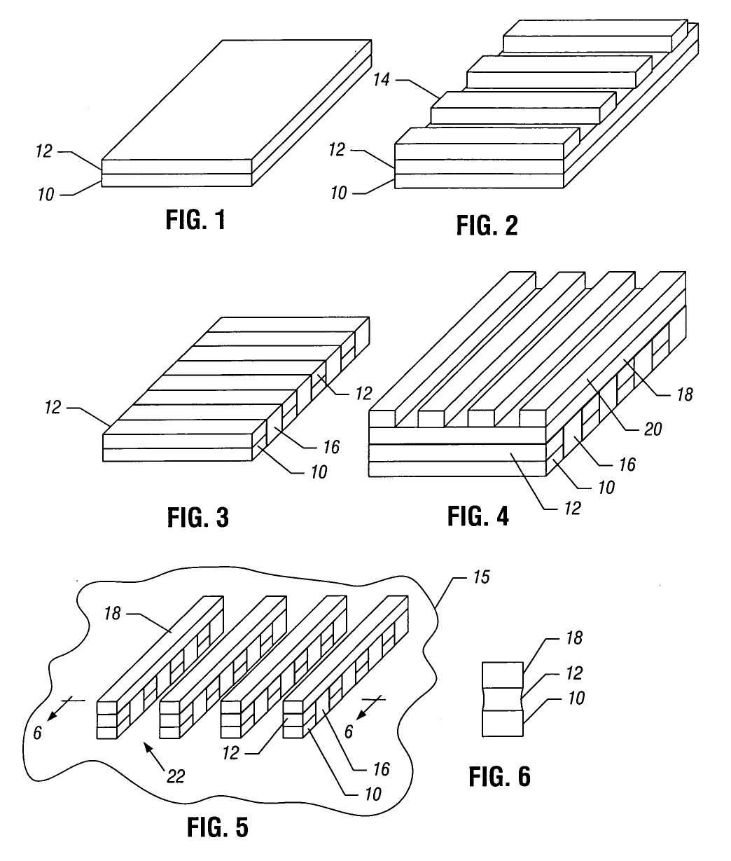

Referring to FIG. 1, a phase change memory array may be formed beginning by blanket depositing a lower electrode 10, covered by a blanket deposited phase change memory layer. In one embodiment, the phase change memory layer 12, which may be formed of a chalcogenide or a pnictide, may be formed in direct contact with the lower electrode 10. The lower electrode may, for example, be titanium silicon nitride.

Then, as shown in FIG. 2, row patterning may be undertaken. A mask 14 is made up of a series of parallel patterns or strips extending in the row direction. The patterns may be formed, for example, of any conventional masking material, including photoresist. In some embodiments, pitch multiplying or direct masking may be used to achieve smaller critical dimensions.

Next, the mask 14 is used to etch all the way through using the stacked phase change material and lower electrode to form segmented elongate strips extending in a row direction. The resulting slots between the strips may be filled with an appropriate dielectric filler 16. Thereafter, the filled structure is planarized to achieve the structure shown in FIG. 3.

Next, a column electrode layer 18 is blanket deposited. The layer 18 may be made of the same or a different material than the lower electrode 10. Then, a column mask 20 may be applied, including parallel strips, extending in a direction transverse to the row direction. The column mask 20 may be applied directly on the structure shown in FIG. 3 or over an intervening barrier layer.

Then, column mask 20 is used to etch completely through the layers, down to the top of the base layer 15, to form the parallel column direction strips shown in FIG. 5. In some cases, the base layer 15 may include an underlying semiconductor substrate. Thus, in the column direction, extending into the page, the successive cells are defined by discrete portions of segmented phase change material 12 arranged in columns. In the transverse direction, rows are defined. Electrical contact to each row may be provided through a row electrode (not shown) extending perpendicularly to the column electrodes, defined from the deposited layer 18, as shown in FIG. 4. The row lines (not shown) may be formed of metallization which may be formed in a substrate, in one embodiment, below the structure shown in FIG. 5.

In some cases, the phase change material 12 may have a reduced critical dimension, as shown in FIG. 6, intermediately along its vertical extent. This reduction may be achieved by exposing the structure shown in FIG. 5 to isotropic etching to result in necking in of the phase change material 12. Advantageously, an etchant that preferentially attacks the phase change material is used.

This necking in narrows the active region. The necking may result in write current reduction in some embodiments.

In some embodiments, a symmetrical, self-aligned structure is achieved in which everything is aligned by virtue of the etching processes illustrated through FIGS. 2 and 4. The symmetric nature of the structure may result in write current reduction. Electrical and thermal symmetry may be achieved by deploying heaterless or symmetric heater electrodes (not shown) and through the cross-section narrowing depicted in FIG. 6, in some embodiments.

In addition, in some embodiments, the peak temperature location can be expected to be at the center of the memory element 12. The boundary of the phase change material 12 is well away from metallurgical interfaces between upper and lower electrode material. Electrical current reduction may achieve effective joule heating due to improved thermal confinement using the phase change material at the top and the bottom of a narrowed region with surrounding dielectric.

In some embodiments, the memory cell active area may be defined by line/space subtractive patterning of the phase change material and the lower electrode with self-aligned upper electrodes to the phase change material. By properly matching the electrical and thermal properties of lower and upper electrodes, a thermally active behavior may be expected for a confined region between and away from upper and lower electrode metallurgical junctions.

In some embodiments, the phase change material 12 may be deposited on top of a flattened or planar surface. This may achieve advantages compared to structures which require the deposition of a phase change material into a pore or hole in a structure.

While no heater is depicted in FIGS. 1-6, in some embodiments, a heater may be applied using the techniques described already. Namely, a heater layer may be deposited, in one example, between the phase change material 12 and the electrode material 10.

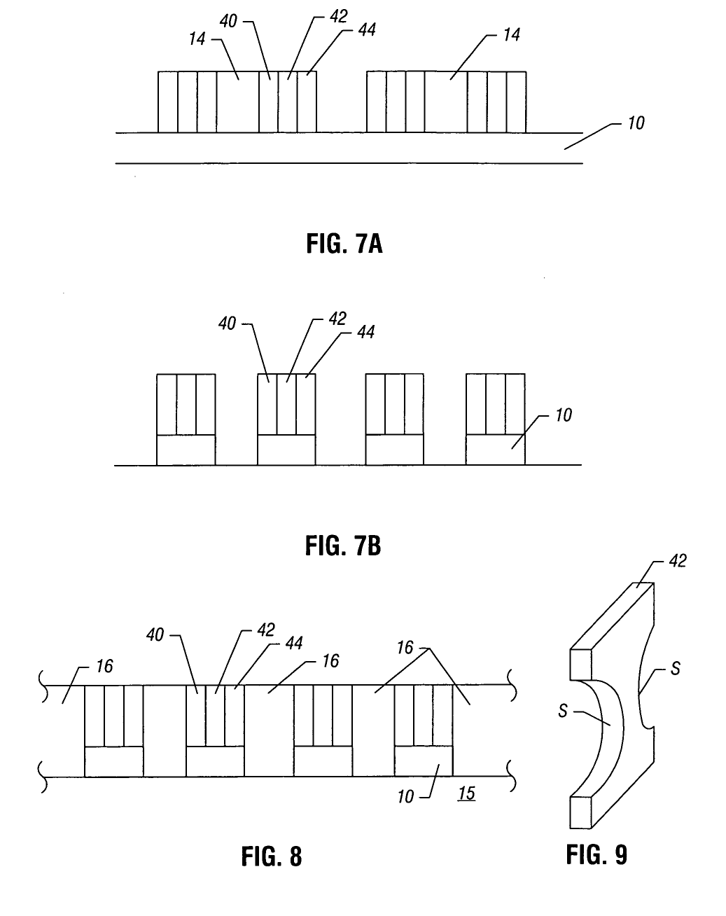

In accordance with another embodiment of the present invention, after blanket depositing the lower electrode 10 on a substrate, the structure may be subjected to pitch multiplying, as shown in FIG. 7A. In some embodiments, a series of sidewall spacers 40, 42, and 44 may be formed on each row mask 14. In one embodiment, the middle spacer 42 may be a phase change material. Dielectric materials may be used for the spacers 40 and 44.

In one embodiment, the spacer 40 may first be formed by blanket deposition over the mask 14. The blanket deposition may then be subjected to anisotropic etch to form a column or sidewall spacer along the side of the row mask 14. Then, layers may be deposited by blanket deposition, one after the other, to form the sidewall spacers 42 and 44. If such a process is used, the sidewall spacer 42 will actually be L-shaped and will extend under the lower edge of the sidewall spacer 44.

As shown in FIG. 7B, the mask 14 is removed by a selective etch to achieve pitch doubled patterning. Also, the lower electrode 10 is etched through to form a dedicated connectivity for phase change material spacer 42.

Thereafter, the slots between the cells are filled by the filler material 16, as shown in FIG. 8. Subsequent processing may be as described in connection with FIGS. 4 and 5.

However, as a result of the use of the sidewall spacer arrangement, isotropic etching, at the step shown in FIG. 5, may result in etching of relatively thin phase change material spacer 42, forming in the indented sidewalls S, as depicted in FIG. 9, and the formation of a necked down region.

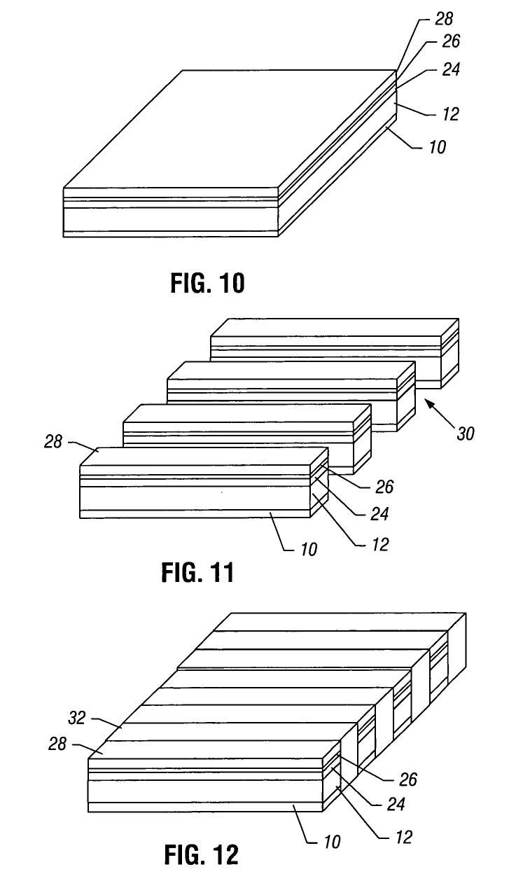

In accordance with another embodiment, an ovonic unified memory may be formed with an ovonic threshold switch using the techniques previously described. Referring to FIG. 10, a stack is formed of blanket deposited successive layers. The lowermost layer, again, corresponds to the lower electrode 10. The next layer may be a layer of phase change material 12. Overlying the phase change material 12 may be a middle electrode 24. Over the middle electrode 24 may be the ovonic threshold switch 26. A top electrode 28 may then be blanket deposited on top of the entire structure shown in FIG. 10.

The ovonic threshold switch 26 may be made up of a sandwich of an electrode layer on the top and bottom with an intervening ovonic threshold switch chalcogenide material in between.

The structure shown in FIG. 10 may then be subjected to row patterning by direct masking or pitch multiplying of the sort described in connection with FIGS. 7 and 8. Thus, a series of row direction extending structures, with intervening, etched gaps 30, results, as shown in FIG. 11.

The structure shown in FIG. 11 may be subjected to gap filling and planarization to produce the filled gaps 32 in a planarized structure shown in FIG. 12.

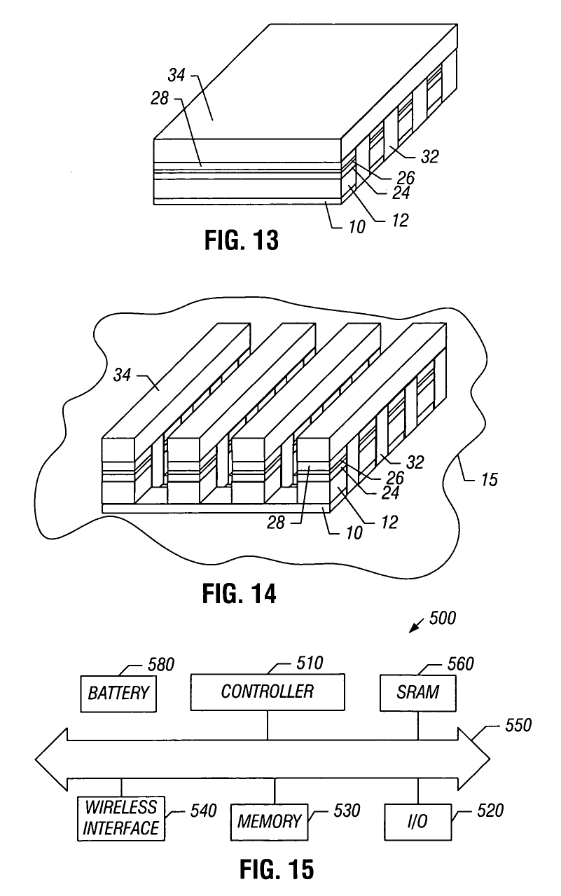

Moving to FIG. 13, a column material 34 may be deposited. The column material 34 may be subjected to column patterning, as described previously, for example, in connection with FIG. 4. A replaced column technique can be deployed with a sacrificial top layer material for damascene column replacement.

The blanket deposited column material 34 may then be subjected to column direction patterning, resulting in the structure shown in FIG. 14, with columns 34 formed thereon. By etching down to, but not through, the lower electrode 10, the row connections are maintained from left to right, across the page, while the column direction connections (into the page) are achieved through the column electrodes 34.

Programming to alter the state or phase of the material may be accomplished by applying voltage potentials to the lower electrode 10 and upper electrode 18, thereby generating a voltage potential across a memory element including a phase change material 12. When the voltage potential is greater than the threshold voltages of any select device and memory element, then an electrical current may flow through the phase change material 12 in response to the applied voltage potentials, and may result in heating of the phase change material 12.

This heating may alter the memory state or phase of the material 12, in one embodiment. Altering the phase or state of the material 12 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 15, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
patterning a structure including a lower electrode material to form a plurality of parallel, spaced first strips extending in a first direction;
planarizing said strips;
patterning the planarized first strips to form a plurality of parallel, spaced second strips extending in a second direction different than said first direction; and
forming a phase change material in one of said first or second strips.

2. The method of claim 1 including forming a stack by blanket depositing a phase change material over said lower electrode material.

3. The method of claim 2 wherein forming said stack includes blanket depositing said phase change material directly on said lower electrode material.

4. The method of claim 2 wherein patterning a structure includes patterning said stack.

5. The method of claim 2 wherein patterning a structure includes etching all the way through said stack.

6. The method of claim 5 wherein patterning the planarized first strips includes etching to form a plurality of second strips extending perpendicularly to said first direction.

7. The method of claim 6 including isotropically etching said second strips to form a necked down phase change material.

8. The method of claim 1 including forming a series of parallel, spaced elongate strips of phase change material over said lower electrode material.

9. The method of claim 8 including forming a plurality of parallel, spaced strips of material over said lower electrode material and forming sidewall spacers on said strips of said material, one of said sidewall spacers including said phase change material.

10. The method of claim 9 including forming a first sidewall spacer of a dielectric, a second sidewall spacer of a phase change material, and a third sidewall spacer of a dielectric material.

11. The method of claim 10 wherein patterning said structure includes using said sidewall spacers as a mask to pattern said structure.

12. The method of claim 11 including isotropically etching said spacer of a phase change material.

13. The method of claim 1 including forming a stack of blanket deposited layers including an ovonic threshold switch material.

14. The method of claim 13 wherein patterning a structure including a lower electrode includes etching to form a plurality of parallel, spaced first strips extending in a first direction by etching all the way through said structure.

15. The method of claim 14 including covering said first strips with a dielectric material.

16. The method of claim 15 wherein patterning the planarized first strips includes etching down to, but not through, said lower electrode material.

17. The method of claim 1 including forming singulated phase change memory material portions self-aligned to said lower electrode and an upper electrode.

18. A phase change memory comprising:
a substrate; and
a plurality of spaced, parallel elongate strips, said strips over said substrate, said strips including a plurality of spaced, singulated phase change memory material portions extending along the length of the strips, said strips including an upper electrode, over said phase change material portion, extending along the length of the strips.

19. The memory of claim 18 including a series of spaced, parallel, lower electrodes, said electrodes extending generally perpendicularly to said strips, said parallel, lower electrodes being located under said phase change memory material portions.

20. The memory of claim 18 wherein said strips are separated from and unconnected to each of the other of said strips except by said substrate.

21. The memory of claim 18 wherein said phase change material portions have indented, exposed surfaces.

22. The memory of claim 18 wherein said phase change memory material portions are sidewall spacers.

23. The memory of claim 22 including dielectric sidewall spacers sandwiching said phase change memory material portions.

24. The memory of claim 18 wherein said strips include an ovonic threshold switch.

25. The memory of claim 18 including lower electrodes under said phase change memory material portions and wherein said phase change memory material portions are self-aligned with upper and lower electrodes.

26. A system comprising:
a processor;
a static random access memory coupled to said processor; and
a phase change memory including a substrate, and a plurality of spaced, parallel elongate strips, said strips over said substrate, said strips including a plurality of spaced, singulated phase change memory material portions extending along the length of the strips, said strips including an upper electrode, over said phase change material portion, extending along the length of the strips.

27. The system of claim 26 including a series of spaced, parallel, lower electrodes, said electrodes extending generally perpendicularly to said strips, said parallel, lower electrodes being located under said phase change memory material portions.

28. The system of claim 26 wherein said strips are separated from and unconnected to each of the other of said strips except by said substrate.

29. The system of claim 26 wherein said phase change material portions have indented, exposed surfaces.
